(19) United States
(12) Patent Application Publication
(10) Pub. No.: US 2025/0237944 A1
(43) Pub. Date: Jul. 24, 2025

(54) ANTI-SLIP COMPOSITIONS AND COMPONENTS FOR SEMICONDUCTOR WAFER HANDLING SYSTEMS

(71) Applicant: Taiwan Semiconductor Manufacturing Company LTD, Hsinchu (TW)

(72) Inventors: Chung-Ming Huang, Tainan (TW); Ren-Guan Duan, Fremont, CA (US); Chiun-Da Shiue, Hsinchu (TW); Chinghao Meng, Hsinchu (TW); Ruei-Hao Fan, Taichung (TW); Nai-Han Cheng, Zhudong (TW)

(21) Appl. No.: 18/421,267

(22) Filed: Jan. 24, 2024

(51) Int. Cl. G03F 7/00; C09K 3/14; H01L 21/67; H01L 21/687

(52) U.S. Cl. CPC G03F 7/0025; C09K 3/149; G03F 7/70033; H01L 21/67225; H01L 21/68707

(57) ABSTRACT

Anti-slip components are made from a polymeric composition that comprises a fluoroelastomer doped with a transition metal ceramic. The fluoroelastomer has excellent chemical resistance and thermal resistance, and the transition metal ceramic increases the static coefficient of friction for the polymeric composition. The anti-slip components are especially suitable for material handling systems that may be exposed to harsh environments in a photolithographic patterning system.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a representative illustration of a three-dimensional fluoroelastomer matrix with transition metal ceramics dispersed therein, in accordance with some embodiments.

FIG. 2 is a flowchart illustrating a first method for forming an anti-slip component, in accordance with some embodiments.

FIG. 3 is a plan view schematic illustrating an automated semiconductor wafer handling system with components that incorporate anti-slip components, in accordance with some embodiments of the present disclosure.

FIG. 4A is a plan view schematic of a robotic arm of an automated semiconductor wafer handling system that incorporates anti-slip components, in accordance with some embodiments of the present disclosure. FIG. 4B is a side view of the robotic arm.

FIG. 5A is a plan view schematic of a robotic platform in an automated semiconductor wafer handling system that incorporates anti-slip components, in accordance with some embodiments of the present disclosure. FIG. 5B is a side view of the robotic platform.

FIG. 6A is a plan view of an anti-slip component, in accordance with some embodiments of the present disclosure.

FIG. 6B is a cross-sectional view of one embodiment having the plan view of FIG. 6A.

FIG. 6C is a cross-sectional view of another embodiment having the plan view of FIG. 6A.

FIG. 7 is a flowchart illustrating a method for moving a semiconductor wafer substrate, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The term “vinyl” refers to a structure of the formula —CX═CX₂, where each X is hydrogen or fluorine.

The term “ether” refers to a structure of the formula —O—, where the oxygen atom is bonded to two different carbon atoms.

The term “alkyl” refers to a structure composed entirely of carbon atoms and hydrogen atoms which is fully saturated (i.e. does not contain double or triple bonds). The alkyl structure may be linear, branched, or cyclic. The alkyl structure may bond to one or two other atoms, depending on the context in which it is used. For example, both methyl (—CH₃) and methylene (—CH₂—) should be considered alkyl structures. As used herein, an alkyl structure contains 1 to 8 carbon atoms. An alkyl structure may be substituted.

The term “aryl” refers to an aromatic structure composed entirely of carbon atoms, and optionally hydrogen atoms along the perimeter of the structure. As used herein, an aryl group has from 6 to about 18 carbon atoms. The term “aryl” should not be construed as including substituted aromatic structures, such as methylphenyl group (7 carbon atoms). The aromatic structure may bond to one or two other atoms, depending on the context in which it is used. For example, both phenyl (—C₆H₅) and phenylene (—C₆H₄—) should be considered aromatic structures. An aryl structure may be substituted.

As used herein, the term “copolymer” refers to a polymeric molecule derived from two or more monomers, as opposed to a homopolymer, which is a molecule derived from only one monomer.

The term “monomer” refers to a molecule that can react with other monomers to form a polymer. A “repeating unit” is derived from a monomer, and they differ in a known manner in their structure. These two terms may be used interchangeably.

The term “up to X” is used in this disclosure to indicate an amount of a given material. This term should be construed to require the given material to be present in an amount greater than zero, or in other words to exclude the value zero.

The average particle size is defined as the diameter at which 50% of the particles have a diameter above the average particle size, and 50% of the particles have a diameter below the average particle size. The size distribution of the particles will be Gaussian, with upper and lower quartiles at 25% and 75% of the stated average particle size, and all particles being less than 150% of the stated average particle size. It is noted that particles do not have to be spherical. For non-spherical particles, the particle diameter is the diameter of a spherical particle having the same volume as the non-spherical particle.

As used herein, the term “anti-slip” refers to the quality of being designed to prevent slips or to be resistant to slipping, which is usually achieved by having a higher static coefficient of friction.

The present disclosure relates to compositions containing fluoroelastomers and articles and components made from such fluoroelastomers, as well as their use in various devices used in semiconductor manufacturing processes.

In this regard, a single wafer will undergo a number of different processing steps that are carried out in different machines/process chambers. For example, steps such as chemical vapor deposition (CVD) or physical vapor deposition (PVD), etching, planarization, cleaning, and/or ion implantation will occur in different process chambers. These process chambers may contain harsh environments, for example high temperatures or chemical/plasma environments. An automated material handling system (AMHS) is often used to handle and move semiconductor wafers between such process chambers. An AMHS often includes a wafer support that engages the semiconductor wafer, such as a robotic arm or platform. The robotic arm may include one or more anti-slip components, such as pads, which actually contact the backside of the semiconductor wafer.

The fluoroelastomer-containing compositions of the present disclosure include a fluoroelastomer and a transition metal ceramic. They can be used to make anti-slip components which have a high static coefficient of friction. This increases the friction between the wafer support and the wafer, which makes it more difficult for the wafer to inadvertently fall off during movement of the robotic arm or platform. This may permit higher acceleration during movement of the AMHS while reducing slippage. This may permit higher wafer throughput.

In particular embodiments, the fluoroelastomers used in the present disclosure are perfluoroelastomers as defined by ASTM D1418. Perfluoroelastomers are copolymers that are usually derived from monomers that include tetrafluoroethylene (TFE) and perfluoroalkyl vinyl ethers (PAVE). Examples of PAVEs include perfluoromethyl vinyl ether and perfluoroethyl vinyl ether.

Perfluoroelastomers usually include a cure site monomer (CSM), which provides a reactive site in the elastomer which can then react to form a three-dimensional matrix or network. CSMs such as a cyano-functional vinyl ether or another CSM containing other functional groups such as nitrile, carboxyl, halogen, or alkoxycarbonyl may be used as well.

Perfluoroelastomers can be cured using a curative, or crosslinking agent, to aid in the formation of a three-dimensional matrix or network. Some non-limiting examples of suitable curatives include triallyl isocyanurate (TAIC); 2,2-bis [3-amino-4-hydroxyphenyl] hexafluoropropane, also known as diaminobisphenol AF or BOAP; phosphonium salts such as fluoroarylalkyl phosphonium salts; tetraphenyl tin; and ammonia.

Perfluoroelastomers may be prepared using any suitable polymerization process. Examples of such processes may include radical polymerization or emulsion polymerization. Polymerization initiators may include organic or inorganic peroxides, azo compounds, persulfates, percarbonates, peresters, and the like.

The fluoroelastomers of the present disclosure are formed from a first reaction mixture that comprises tetrafluoroethylene (TFE), a perfluoroalkyl vinyl ether (PAVE), a curative, and a polymerization initiator. For purposes of this first reaction mixture only, with respect to the term “parts per hundred rubber” or “phr”, only the tetrafluoroethylene (TFE) and the perfluoroalkyl vinyl ether (PAVE) are considered to form the rubber. PHR is also used as a measure of weight in the present disclosure, and not mole percent or volume percent. In some particular embodiments, the curative may comprise up to 5 phr of the reaction mixture. Other ranges and values are also within the scope of this disclosure.

In some embodiments, the molar ratio of the TFE to the PAVE in the fluoroelastomer may range from about 5:95 to about 95:5, including from about 15:85 to about 85:15, or from about 30:70 to about 70:30, or from about 40:60 to about 60:40. In some other embodiments, the molar ratio of TFE to PAVE is from about 5:95 to about 65:35, or from about 65:5 to about 95:5. Other combinations of ranges with these values are also contemplated, and other ranges and values are also within the scope of this disclosure.

The polymerization of the various components in the reaction mixture is performed at conventional temperatures, times, and pressures. The resulting fluoroelastomer forms a three-dimensional matrix due to crosslinking between different polymer strands.

Each polymer strand backbone may have the general formula of Formula (I):

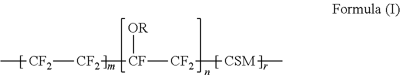

where m is the molar ratio of the TFE, n is the molar ratio of the PAVE, and r is the molar ratio of any cure site monomer, and wherein 0.05≤m, n≤0.95 and 0≤r≤0.10, and m+n+r=1; and R is alkyl having 1 to about 4 carbon atoms.

Next, a second reaction mixture is formed that includes the fluoroelastomer, a transition metal ceramic, and a curative. This reaction mixture is then reacted at conventional temperatures, times, and pressures. The fluoroelastomer is thus doped with the transition metal ceramic. Due to the presence of the curative, crosslinks are formed within the fluoroelastomer.

The transition metal ceramic is, in particular embodiments, an oxide, carbide, or a nitride. More particularly, the transition metal may be scandium, titanium, vanadium, chromium, manganese, iron, cobalt, nickel, copper, zinc, yttrium, zirconium, niobium, molybdenum, technetium, ruthenium, rhodium, palladium, silver, cadmium, lutetium, hafnium, tantalum, tungsten, rhenium, osmium, iridium, platinum, or silver. In particular embodiments, the transition metal has an electronegativity of about 1.0 to about 2.3. In even more specific embodiments, the transition metal ceramic is titanium carbide (TiC) or yttrium oxide (Y₂O₃). In particular embodiments, the transition metal may have an average particle size of about 60 nanometers to about 5 micrometers, and in more particular embodiments an average particle size of from about 1 micrometer to about 5 micrometers. In even more particular embodiments, the transition metal ceramic is Y₂O₃ having an average particle size of from about 1 micrometer to about 5 micrometers. In particular embodiments, the transition metal ceramic comprises from about 10 phr to about 12 phr of the polymeric composition. For purposes of this second reaction mixture, the term phr refers to the fluoroelastomer as the rubber. Other ranges and values are also within the scope of this disclosure. A lower amount of the transition metal ceramic reduces the generation of particulate contaminants from erosion of the polymeric composition.

In some particular embodiments, the curative may comprise up to 5 phr of the second reaction mixture. Other ranges and values are also within the scope of this disclosure. Similar curatives may be used in the second reaction mixture as described above for the first reaction mixture.

If desired, the second reaction mixture may also include at least one filler, which can improve desirable properties such as compression set, chemical resistance, plasma resistance, or other mechanical properties. In particular embodiments, the filler is silicon dioxide (SiO₂). In particular embodiments, the filler comprises from about 1 phr to about 3 phr of the polymeric composition. In particular embodiments, the filler may have an average particle size of about 10 nanometers to about 50 nanometers, and in more particular embodiments an average particle size of from about 10 nanometers to about 20 nanometers. Other ranges and values are also within the scope of this disclosure.

Other additives may also be added to the second reaction mixture/polymeric composition. Examples of such additives may include cure accelerators, co-curatives, co-agents, processing aids, plasticizers, and other modifiers. Additional examples of additives may include carbon black, clay, talc, metallic fillers such as aluminum oxide (Al₂O₃), metal carbides, metal nitrides, colorants, organic dyes and/or pigments, and the like.

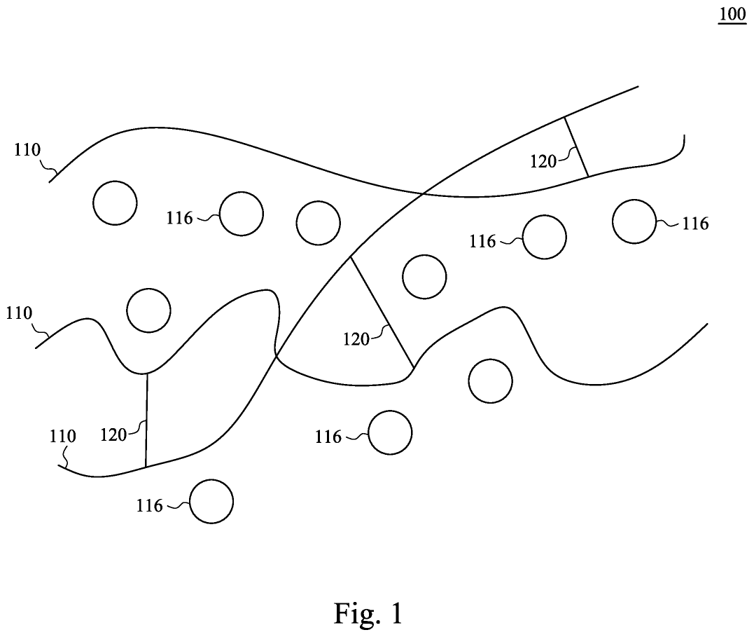

The resulting polymeric composition is representatively illustrated in FIG. 1. The fluoroelastomer 100 forms a three-dimensional matrix due to crosslinking between different polymer strands. Here, three polymer strands 110 are illustrated. Crosslinks 120 are formed between the polymer strands due to the curative present in the first reaction mixture. The transition metal ceramic particles are represented by circles 116. The particles are well dispersed in the matrix.

The polymeric compositions can be formed into a molded article by placing the polymeric composition into a mold and applying heat and pressure within the mold, for example by compression molding, to make an article having the desired shape. The polymeric composition can be put into the mold as a gum or paste, or placed into the mold as a rubber and then cured. In particular embodiments, the article formed from compositions containing the perfluoroelastomers of the present disclosure is an anti-slip component, which can be used in an AMHS. Its high static coefficient of friction reduces slippage. Its high chemical resistance and thermal resistance permits exposure to harsh environments, for example those in plasma treatment chambers.

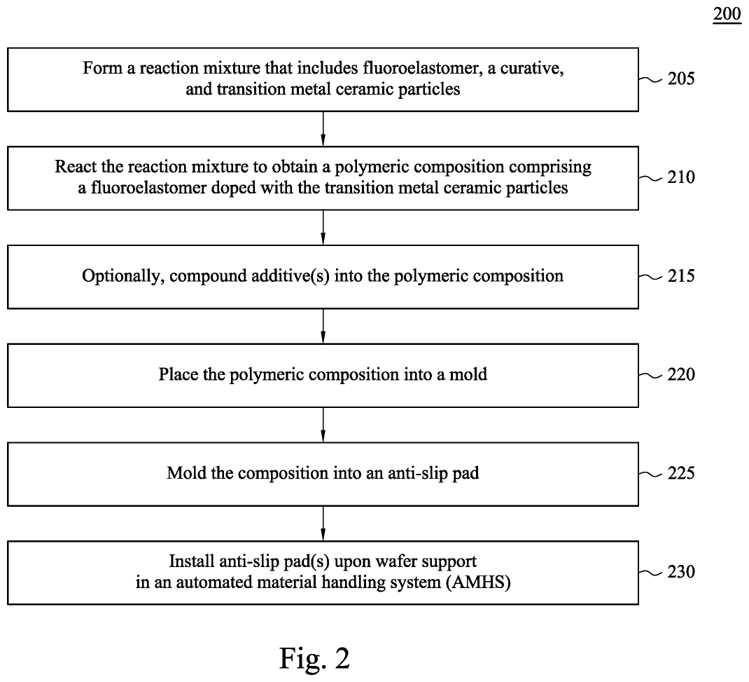

Summarizing, then, FIG. 2 is a flowchart illustrating a first method 200 for forming an anti-slip component from the fluoroelastomer-containing polymeric compositions of the present disclosure, in accordance with some embodiments. In step 205, a reaction mixture is formed that includes a fluoroelastomer, a curative, and a transition metal ceramic. In step 210, the reaction mixture is reacted to obtain a polymeric composition comprising a fluoroelastomer. The transition metal ceramic is dispersed within the fluoroelastomer, or can be described as doping the fluoroelastomer. The fluoroelastomer may be in the form of a matrix formed from fluoroelastomer strands. In optional step 215, additives may be compounded into the polymer matrix of the polymeric composition. In step 220, the polymeric composition is placed into a mold. In step 225, the composition is molded into an anti-slip component. This may be performed, for example, by the application of suitable pressure and heat. Going further, in step 230, the anti-slip component is attached to a wafer support in an automated material handling system (AMHS).

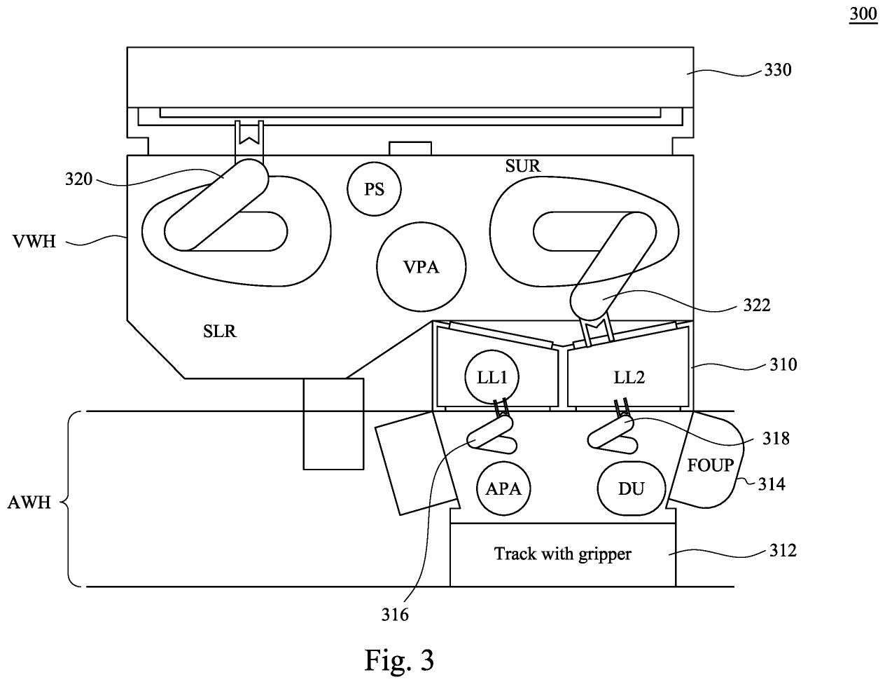

FIG. 3 is a plan view schematic diagram illustrating an example of an automated material handling system (AMHS) 300 used for handling semiconductor wafers during processing. In this example, the system includes an atmospheric wafer handling (AWH) module and a vacuum wafer handling (VWH) module which are linked to each other through a load-lock apparatus 310.

The load-lock apparatus 310 is illustrated as having two load-lock chambers LL1 and LL2. As illustrated here, LL1 is used to transfer wafer substrates from the AWH module to the VWH module. LL2 is used to transfer wafer substrates from the VWH module to the AWH module. This improves throughput.

Referring next to the AWH module, two different locations are illustrated from which a wafer substrate can be received. The first location 312 is a track with a gripper which can receive a wafer substrate directly from another processing tool, such as a coating and development tool. The second location 314 is a FOUP (Front Opening Unified Pod), which can be used to store semiconductor wafer substrates between process steps and for transportation between various processing machines/tools.

The AWH module includes an Atmospheric Load Robot (ALR) 316 and an Atmospheric Unload Robot (AUR) 318, which are located proximate LL1 and LL2, respectively. Each of these robots may include a robotic arm which has one or more anti-slip components mounted thereon. The AWH module also includes an Atmospheric Pre Align (APA) position and a Discharge Unit (DU) position. In this regard, a small notch is usually cut into the wafer substrate for alignment in a repeatable orientation during each processing step. The APA is used to identify the orientation of the wafer substrate, so the wafer substrate can be properly oriented prior to being picked up by the ALR and loaded into LL1. The AUR retrieves the wafer substrate from LL2 and moves it to the DU position or into the FOUP, as appropriate. The DU position is used as a storage position to permit orientation before a wafer substrate is picked up by the gripper and returned back to the first location 310 and the processing tool located there. The gripper may include a robotic arm which has one or more anti-slip components mounted thereon. Both the APA and the DU may be a platform which can be raised or lowered, and may have one or more anti-slip components mounted thereon.

As illustrated here, the VWH module includes a Stage Load Robot (SLR) 320 and a Stage Unload Robot (SUR) 322. Each of these robots may include a robotic arm which has one or more anti-slip components mounted thereon. The VWH modules also includes a Park Station (PS) position and a Vacuum Pre-Align (VPA) position. The SLR retrieves a wafer substrate from LL1 and moves the wafer substrate to the VPA position. At the VPA position, the wafer substrate can be deposited and its orientation verified again for proper pick-up by the SLR. The SLR can deposit the wafer substrate at the PS position to provide thermal control for the wafer substrate and the SLR prior to inserting the wafer substrate into a vacuum-pressure processing tool 330. The vacuum-pressure processing tool may be, for example, an EUV photolithography system, with the VWH module being a part of the EUV photolithography tool. The SUR retrieves the wafer substrate from the vacuum-pressure processing tool 330 and inserts it into LL2. It is noted that the VWH module may be part of the vacuum-pressure processing tool 330, or may be a separate module. Again, both the PS and the VPA may be a platform which can be raised or lowered, and may have one or more anti-slip components mounted thereon. The vacuum-pressure processing tool 330 is just one example of a possible process module. Another example may be a plasma etching tool, where the plasma environment may create ions which can attack the anti-slip pad material, or where the anti-slip components may be exposed to high temperatures.

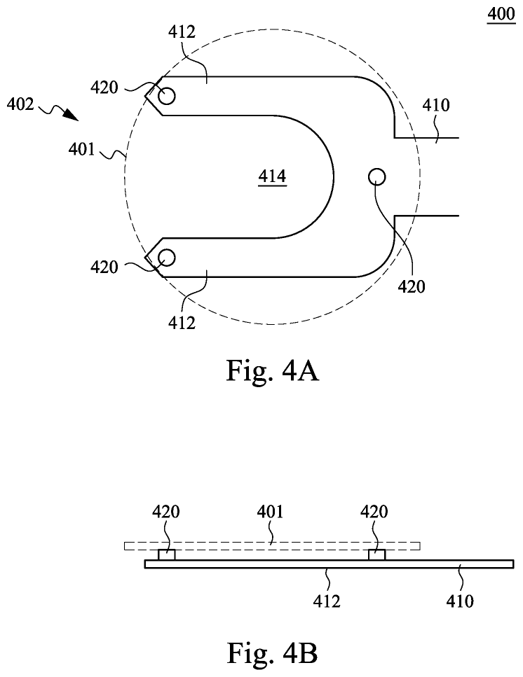

FIG. 4A and FIG. 4B are different views of a portion of one embodiment of a wafer support 400, which is illustrated as a robotic arm that incorporates anti-slip components, such as anti-slip pads, in accordance with some embodiments of the present disclosure. FIG. 4A is a plan view, and FIG. 4B is a side view.

Referring to both figures, the end effector portion 402 of the robotic arm is illustrated. The end effector portion includes a bearing portion 410 which links to the rest of the robotic arm (not illustrated), and also includes two tines 412 which extend from the bearing portion and will slide underneath the wafer 401 (shown in dotted line). As illustrated here, there are three anti-slip pads 420 on the end effector portion. The three anti-slip pads are placed so as to be located roughly uniformly around the perimeter of the wafer, so as to reduce the likelihood of the wafer tipping off of the end effector portion. One anti-slip pad is located at the end of each tine, and one is located near the bearing portion. The anti-slip pads extend upward from the surface of the tines to support the wafer above the tines. This reduces the amount of wafer area contacted by the tines. The tines are spaced horizontally apart so as to leave a void 414 between them. This may be useful, for example, so that the tines can travel to either side of another wafer support (such as a robotic platform) while holding a wafer. The end effector can then travel downwards, leaving the wafer on the other wafer support. The rest of the robotic arm may include additional joints and linkages to provide additional degrees of freedom for moving and handling the wafer substrate.

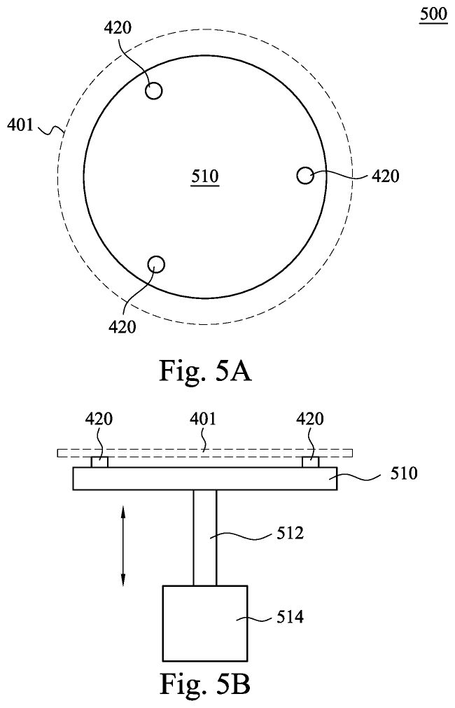

FIG. 5A and FIG. 5B are different views of a second embodiment of a wafer support 500, which is illustrated as a robotic platform that incorporates anti-slip components, such as anti-slip pads, in accordance with some embodiments of the present disclosure. FIG. 5A is a plan view, and FIG. 5B is a side view.

Referring to both figures, the platform includes a horizontal stage 510 which is supported by a vertical piston 512 that can move vertically relative to a base 514. As illustrated here, there are three anti-slip pads 420 on the horizontal stage. The three anti-slip pads are placed so as to be located roughly uniformly around the perimeter of the stage and the wafer 401. Again, the anti-slip pads also elevate the wafer above the stage.

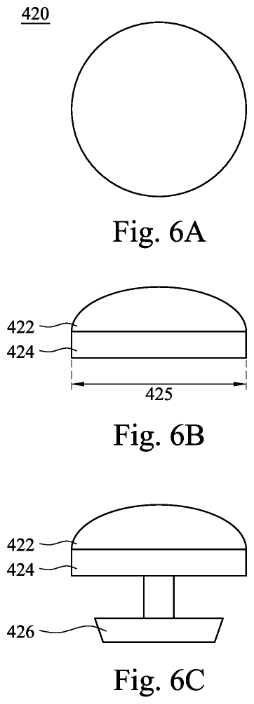

The anti-slip components may be shaped as desired, for example as pads, sheets, mats, etc. FIG. 6A is a top plan view of some embodiments of an anti-slip pad 420. FIG. 6B is a cross-sectional view of one embodiment having the plan view of FIG. 6A. FIG. 6C is a cross-sectional view of another embodiment having the plan view of FIG. 6A.

Referring first to FIG. 6A, the anti-slip pad 420 is illustrated as having a circular shape. Any desired shape may be used, for example, rectangular, square, etc. Generally, however, it is desired to minimize the contact surface area, so as to minimize the generation of particulate contaminants, whether from the anti-slip pad or from the wafer.

As seen in FIG. 6B, the anti-slip pad 420 has a curved upper surface 422, which aids in minimizing the contact surface area. A lower base 424 of the pad is rectangular, and can be used for attachment to the robotic arm or platform. The diameter or width 425 of the pad may range, in particular embodiments, from 1/16 of an inch to about 1 inch. By way of comparison, the diameter of a semiconductor wafer may range up to 450 mm (˜17.7 inches).

In the embodiment of FIG. 6C, a snap-fit joint 426 extends from the lower surface of the base 424. It is contemplated that this snap-fit joint would interface with an aperture in the robotic arm or platform, to lock the anti-slip pad into place.

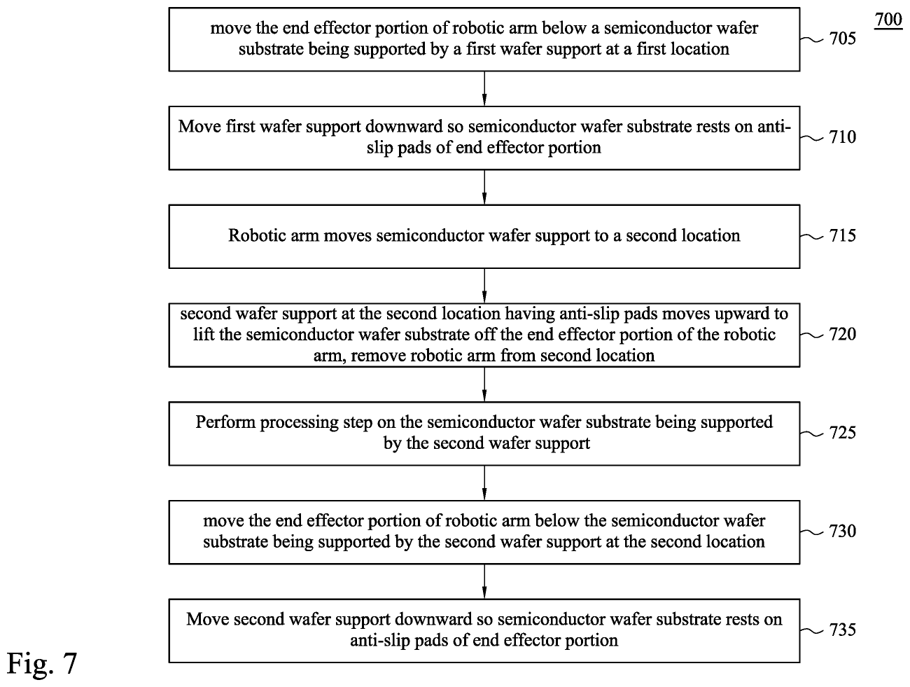

FIG. 7 is a flowchart illustrating a method 700 for moving a semiconductor wafer substrate, according to some embodiments of the present disclosure. The method will be described with reference to both a robotic arm and a robotic platform, and for moving the wafer to the robotic platform, and will refer back to the system of FIG. 3 as a non-limiting example. However, the discussion should also be broadly construed as applying to the use of either one of these robotic devices, and moving the wafer from any given location to another location.

In step 705, a robotic arm moves an end effector portion underneath a semiconductor wafer substrate being supported by a first wafer support. The first wafer support is present in a first location, and has one or more anti-slip pads thereon. Referring to FIG. 3, the first location may be the APA location, and the robotic arm may be robotic arm 316. The end effector portion may be as illustrated in FIGS. 4A-4B.

In step 710, the first wafer support moves downward. As a result, the semiconductor wafer substrate contacts anti-slip pads present on the end effector portion. In step 715, the robotic arm moves the semiconductor wafer substrate to a second location. Referring to FIG. 3, the second location may be LL1. A door or valve may be present between the two locations, and may be opened and closed as appropriate.

In step 720, a second wafer support at the second location moves upward to lift the semiconductor wafer substrate off of the end effector portion of the robotic arm. The second wafer support also has one or more anti-slip pads thereon. The robotic arm can then withdraw from the second location. In step 725, a processing step occurs to the semiconductor wafer support (although not applicable in FIG. 3). The second wafer support may be a robotic platform as illustrated in FIGS. 5A-5B. While the robotic arm is withdrawn, the robotic platform may move vertically as needed for any desired application, for example to permit access by another arm such as arm 320.

In step 730, the robotic arm returns to the second location and moves the end effector portion underneath the semiconductor wafer substrate being supported by the second wafer support. In step 735, the second wafer support moves downward. This results in the semiconductor wafer substrate being removed from the second wafer support and again being supported by the anti-slip pads present on the end effector portion. The robotic arm may then move the semiconductor wafer substrate to any desired location.

Use of the fluoroelastomers of the present disclosure for making anti-slip components for use with wafer supports offers several advantages. The anti-slip components have a higher coefficient of friction, and so a higher friction force exists between the wafer and the anti-slip component. Wear resistance is also improved, which reduces generation of contaminating particulates. This thus permits higher accelerations to be used for the robotic arm, which may result in higher throughput. The anti-slip component has good chemical resistance and plasma resistance, which permits its use in harsh environments between different process chambers.

The present disclosure thus relates in various embodiments to automated semiconductor wafer handling systems comprising a robotic arm or platform having at least one anti-slip component mounted thereon. The anti-slip component is formed from a polymeric composition comprising a fluoroelastomer doped with a transition metal ceramic.

Also disclosed in various embodiments are methods for using an anti-slip component. The anti-slip component is attached to a wafer support. The anti-slip component is formed from a polymeric composition comprising a fluoroelastomer doped with a transition metal ceramic.

Other embodiments disclosed herein relate to methods for forming an anti-slip component. A polymeric composition is placed into a mold, and then molded to form the anti-slip component. The polymeric composition comprises a fluoroelastomer doped with a transition metal ceramic.

Also disclosed herein are various methods for making a fluoroelastomer doped with a transition metal ceramic. A reaction mixture that comprises the fluoroelastomer, the transition metal ceramic, and a curative is reacted to obtain the doped fluoroelastomer.

Also disclosed are anti-slip components formed from a polymeric composition comprising a fluoroelastomer doped with a transition metal ceramic.

The methods, polymers, systems, and devices of the present disclosure are further illustrated in the following non-limiting working examples, it being understood that they are intended to be illustrative only and that the disclosure is not intended to be limited to the materials, conditions, process parameters and the like recited herein.

### EXAMPLES

In Examples E1-E6, multiple fluoroelastomers were prepared with different fillers. Their coefficient of friction was measured by making a pad from the fluoroelastomer, placing the pad upon a piece of glass, placing a weight upon the pad, and measuring the force needed to move the pad. The results are provided in Table A below. In Example E2, L/C stands for “length and cross-section”.

TABLE A

| | E1 | E2 | E3 | E4 | E5 | E6 |
|---|---|---|---|---|---|---|
| Polymer | FFKM | FFKM | FFKM | FFKM | FFKM | FFKM |
| Cross-link | 2.5 phr | 2.5 phr | 2.5 phr | 2.5 phr | 1.5 phr | 1.5 phr |
| structure | Triazine | Triazine | Triazine | Triazine | TAIC | TAIC |
| | curative | curative | curative | curative | | |
| Filler-1 and | 10 phr SiC | 10 phr SiC | 10 phr TiC | 10 phr | 10 phr | 10 phr |
| particle size | 100 nm | fibers | 75 nm | Y2O3 | TiC | Y2O3 |
| | | L/C = 30/0.5 | | 3 μm | 75 nm | 3 μm |
| | | μm | | | | |
| Filler-2 and | — | — | — | — | 2 phr | 2 phr |
| particle size | | | | | SiO2 | SiO2 |
| | | | | | 16 nm | 16 nm |
| Friction | 0.66 | 0.75 | 0.75 | 0.99 | 0.86 | 0.97 |
| Coefficient | | | | | | |

Comparing Examples E1 and E2 to Example E3, the use of a transition metal ceramic instead of SiC improved the friction coefficient by over 13%. Comparing Example E3 to Example E4, the use of Y₂O₃ over TiC and at a larger particle size improved the friction coefficient by a further 32%. Comparing Example E3 to Example E5, the addition of a small amount of SiO₂ also improved the friction coefficient by almost 15%.

Next, Example E6 was tested again and compared to a commercial composition labeled C1, which was an FFKM perfluoroelastomer that does not contain transition metal ceramic. The friction of each composition was measured. An abrasion test was also applied to each composition, and the weight loss was measured. The results are provided in Table B below. It is noted that the friction results of Table B cannot be directly compared to Table A, due to differences in the testing parameters.

TABLE B

| | C1 | E6 |
|---|---|---|
| Friction coefficient | 0.38 | 0.55 |
| Weight loss | 15.2% | 3.0% |

As can be seen here, Example E6 had a higher friction coefficient and less weight loss during abrasion. In addition, C1 was damaged after the abrasion test, whereas E6 was still intact. E6 thus performed better than C1.

Next, Example E6 was compared again to two commercial compositions labeled C2 and C3. C2 was an FFKM/FKM polymer with no filler. C3 was a polymer which did not contain fluorine, but did contain filler. The friction of each composition was measured. The results are provided in Table C below. Again, the friction results of Table C cannot be directly compared to Tables A or B, due to differences in the testing parameters.

TABLE C

| | C2 | C3 | E6 |
|---|---|---|---|
| Polymer Matrix | FFKM/FKM | (no F) | FFKM |
| Filler | — | 53% SiO2 | 10 phr Y2O3 |
| | | (2-15 μm) | 2 phr SiO2 |
| Friction coefficient | 0.408 | 0.286 | 0.676 |

Comparing C2 to E6, the addition of the fillers including a transition metal ceramic improved the friction coefficient by almost 66%. Comparing C2 to C3, the use of a fluoroelastomer clearly improved the friction coefficient. Comparing C2 to E6, the use of even a very high amount of SiO₂ did not raise the friction coefficient, and such a high amount also increases particulate generation during the service life of the anti-slip pad.

Example E6 was compared again to another commercial composition (DuPont 8900) labeled C4. The friction of each composition was measured at two different temperatures. The results are provided in Table D below. Again, the friction results of Table D cannot be directly compared to any of Tables A-C, due to differences in the testing parameters.

TABLE C

| | C4 | E6 |
|---|---|---|
| Friction coefficient | 0.43 | 0.48 |
| Friction coefficient (250° C.) | 0.39 | 0.44 |

At both temperatures, Example E6 had a higher friction coefficient.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An automated semiconductor wafer handling system comprising a robotic arm or platform having at least one anti-slip component mounted thereon;
wherein the anti-slip component is formed from a polymeric composition comprising a fluoroelastomer doped with a transition metal ceramic.

2. The system of claim 1, wherein a transition metal of the transition metal ceramic has an electronegativity of about 1.0 to about 2.3.

3. The system of claim 1, wherein the transition metal ceramic is titanium carbide (TiC) or yttrium oxide (Y₂O₃).

4. The system of claim 1, wherein an average particle size of the transition metal ceramic is from about 60 nanometers to about 5 micrometers.

5. The system of claim 1, wherein the transition metal ceramic is yttrium oxide (Y₂O₃) having an average particle size of from about 1 micrometer to about 5 micrometers.

6. The system of claim 1, wherein the transition metal ceramic comprises from about 10 phr to about 12 phr of the polymeric composition.

7. The system of claim 1, wherein the polymeric composition further comprises a silicon oxide (SiO₂) filler.

8. The system of claim 7, wherein the SiO₂ filler comprises from about 1 phr to about 3 phr of the polymeric composition.

9. The system of claim 1, wherein the polymeric composition comprises up to 5 phr of a curative.

10. The system of claim 9, wherein the curative is triallyl isocyanurate or a fluoroarylalkyl phosphonium salt.

11. A method for using an anti-slip component, comprising:
attaching the anti-slip component to a wafer support;
wherein the anti-slip component is formed from a polymeric composition comprising a fluoroelastomer doped with a transition metal ceramic.

12. The method of claim 11, wherein a transition metal of the transition metal ceramic has an electronegativity of about 1.0 to about 2.3.

13. The method of claim 11, wherein the transition metal ceramic is titanium carbide (TiC) or yttrium oxide (Y₂O₃).

14. The method of claim 11, wherein an average particle size of the transition metal ceramic is from about 60 nanometers to about 5 micrometers.

15. The method of claim 11, wherein the transition metal ceramic is yttrium oxide (Y₂O₃) having an average particle size of from about 1 micrometer to about 5 micrometers.

16. The method of claim 11, wherein the transition metal ceramic comprises from about 10 phr to about 12 phr of the polymeric composition.

17. The method of claim 11, wherein the polymeric composition further comprises a silicon oxide (SiO₂) filler.

18. The method of claim 17, wherein the SiO₂ filler comprises from about 1 phr to about 3 phr of the polymeric composition.

19. A method for forming an anti-slip component, comprising:
placing a polymeric composition into a mold; and
molding the polymer composition to form the anti-slip component;
wherein the polymeric composition comprises a fluoroelastomer doped with a transition metal ceramic.

20. The method of claim 19, wherein the reaction mixture further comprises a silicon oxide (SiO₂) filler.
